(19) United States
(12) Patent Application Publication
(10) Pub. No.: US 2015/0097250 A1
(43) Pub. Date: Apr. 9, 2015

(54) Semiconductor Devices and Methods for Fabricating the Same

(71) Applicant: Samsung Electronics Co., Ltd., Suwon-si (KR)

(72) Inventors: Keon-Yong CHEON, Yongin-si (KR); Jun-suk CHOI, Hwaseong-si (KR); Han-Su OH, Yongin-si (KR); Yoshinao HARADA, Seongnam-si (KR)

(21) Appl. No.: 14/327,666

(22) Filed: Jul. 10, 2014

(30) Foreign Application Priority Data
Oct. 7, 2013 (KR) 10-2013-0119186

(51) Int. Cl. H01L 27/088; H01L 29/08; H01L 29/423; H01L 29/78; H01L 29/51

(52) U.S. Cl. CPC H01L 27/0886; H01L 29/7851; H01L 29/7853; H01L 29/517; H01L 29/512; H01L 29/42376; H01L 29/0847
USPC 257/401

(57) ABSTRACT

Provided is a semiconductor device, which includes a first fin on a substrate, a first gate insulating layer including a first trench disposed on the first fin, a first work function adjusting layer in the first trench, a first barrier layer covering a top surface of the first work function adjusting layer; and an interlayer insulating layer on the first barrier layer.

### CROSS-REFERENCE TO RELATED APPLICATION

This application claims priority from Korean Patent Application No. 10-2013-0119186 filed on Oct. 7, 2013 in the Korean Intellectual Property Office, and all the benefits accruing therefrom under 35 U.S.C. §119, the contents of which in its entirety are herein incorporated by reference.

### TECHNICAL FIELD

The present inventive concept relates to semiconductor devices and methods for fabricating the same.

### BACKGROUND

As a feature size of a MOS transistor is reduced, a length of a gate and a length of a channel that is formed below the gate may also be reduced. Therefore, various studies for increasing a capacitance between the gate and the channel and improving an operation characteristic of the MOS transistor have been performed.

### SUMMARY

The present inventive concept has been made in an effort to provide semiconductor devices in which product reliability may be improved by reducing a resistance of a gate and preventing a threshold voltage of the gate from being changed.

The present inventive concept is directed to providing methods for fabricating a semiconductor device in which a product reliability may be improved by reducing a resistance of a gate and preventing a threshold voltage of the gate from being changed.

Technical objects of the present inventive concept are not limited to the aforementioned technical objects and other technical objects which are not mentioned will be apparently appreciated by those skilled in the art from the following description.

Some embodiments of the present inventive concept include a semiconductor device that includes a first fin on a substrate and that extends in a first direction, a first gate insulating layer including a first trench disposed on the first fin and that extends in a second direction that is different from the first direction, a first work function adjusting layer in the first trench, a first barrier layer that is configured to cover a top surface of the first work function adjusting layer, and an interlayer insulating layer on the first barrier layer.

In some embodiments, the first work function adjusting layer includes a second trench that is smaller than the first trench and the device further includes a first gate metal that is configured to fill the second trench. Some embodiments provide that the first barrier layer and the first gate metal include the same material. In some embodiments, a cross-section formed by the first barrier layer and the first gate metal includes a T shape.

Some embodiments include a second work function adjusting layer between the first gate insulating layer and the first work function adjusting layer. In some embodiments, the second work function adjusting layer includes a third trench and the first work function adjusting layer is disposed in the third trench.

Some embodiments provide that the first gate insulating layer and the first work function adjusting layer are not in contact with the interlayer insulating layer. In some embodiments, the substrate includes a first region having the first fin that is formed on the top surface thereof and a second region. Some embodiments include a second fin in the second region, a second gate insulating layer disposed on the second fin and that includes a fourth trench, a third work function adjusting layer that includes a fifth trench in the fourth trench, a fourth work function adjusting layer in the fifth trench and a second barrier layer covering a top surface of the fourth work function adjusting layer. In some embodiments, the fourth work function adjusting layer includes a sixth trench that is smaller than the fifth trench. Some embodiments include a second gate metal that fills the sixth trench. In some embodiments, the second barrier layer and the second gate metal include the same material.

In some embodiments, the interlayer insulating layer includes an oxygen atom and the first work function adjusting layer includes TiN. Some embodiments provide that a resistivity of the first barrier layer is lower than a resistivity of the first work function adjusting layer and a resistivity of the first gate insulating layer.

Some embodiments of the present inventive concept include semiconductor devices. A semiconductor device according to such embodiments includes a substrate that includes a first region and a second region, a first fin on the first region and that extends in a first direction, a second fin on the second region and that extends in the first direction, a first gate structure that includes a first width and that is disposed on the first fin, a second gate structure that includes a second width that is different from the first width and that is disposed on the second fin, a first barrier layer that is configured to cover a top surface of the first gate structure, a second barrier layer that is configured to cover a top surface of the second gate structure, and an interlayer insulating layer that is configured to cover the first barrier layer and the second barrier layer.

In some embodiments, the first gate structure includes a first gate insulating layer that includes a first trench that extends in a second direction that is different from the first direction, a first work function adjusting layer that includes a second trench in the first trench and a first gate metal that is configured to fill the second trench. Some embodiments provide that the second gate structure includes a second gate insulating layer that includes a third trench and a second work function adjusting layer that is configured to fill the third trench. In some embodiments, the first width is larger than the second width. Some embodiments provide that the first gate metal and the first barrier layer include the same material.

Some embodiments of the present inventive concept include semiconductor devices. A semiconductor device according to such embodiments includes a fin on a substrate and that extends in a first direction, a source and a drain that are elevated relative to the fin and that are formed spaced apart from one another in the first direction, a first interlayer insulating layer formed on the substrate and on the source and drain, a first gate insulating layer formed in the first interlayer insulating layer and including a first trench disposed on the first fin and that extends in a second direction that is different from the first direction, a first work function adjusting layer in the first trench, a first barrier layer that is configured to cover a top surface of the first work function adjusting layer, and a second interlayer insulating layer on the first barrier layer and on the first interlayer insulating layer.

In some embodiments, the first work function adjusting layer includes a second trench that is smaller than the first trench. The device may include a first gate metal that is configured to fill the second trench. Some embodiments provide that the first barrier layer and the first gate metal include the same material.

Some embodiments include a second work function adjusting layer between the first gate insulating layer and the first work function adjusting layer. In some embodiments, the second work function adjusting layer includes a third trench and the first work function adjusting layer is disposed in the third trench.

Some embodiments include a contact that passes through the first and second interlayer insulating layers and that contacts the source and drain. In some embodiments, the first gate insulating layer and the first work function adjusting layer are not in contact with the second interlayer insulating layer.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE DRAWINGS

The above and other objects, features and advantages of the present inventive concept will be more apparent from the following detailed description taken in conjunction with the accompanying drawings.

FIG. 1 is a perspective view illustrating a semiconductor device according to some embodiments of the present inventive concept.

FIG. 2 is a cross-sectional view of the semiconductor device taken along line A-A of FIG. 1.

FIG. 3 is a cross-sectional view of the semiconductor device taken along line B-B of FIG. 1.

FIG. 4 is a perspective view illustrating a semiconductor device according to some embodiments of the present inventive concept.

FIG. 5 is a cross-sectional view of the semiconductor device taken along line A-A of FIG. 4.

FIG. 6 is a perspective view illustrating a semiconductor device according to some embodiments of the present inventive concept.

FIG. 7 is a cross-sectional view of the semiconductor device taken along line A-A of FIG. 6.

FIG. 8 is a perspective view illustrating a semiconductor device according to some embodiments of the present inventive concept.

FIG. 9 is a cross-sectional view of the semiconductor device taken along line A-A of FIG. 8.

FIG. 10 is a perspective view illustrating a semiconductor device according to some embodiments of the present inventive concept.

FIG. 11 is a cross-sectional view of the semiconductor device taken along line A-A of FIG. 10.

FIG. 12 is a cross-sectional view of the semiconductor device taken along line B-B of FIG. 10.

FIG. 13 is a perspective view illustrating a semiconductor device according to some embodiments of the present inventive concept.

FIG. 14 is a cross-sectional view of the semiconductor device taken along line A-A of FIG. 13.

FIG. 15 is a cross-sectional view of the semiconductor device taken along line B-B of FIG. 13.

FIGS. 16 and 17 are a circuit diagram and a layout diagram illustrating a semiconductor device according to some embodiments of the present inventive concept.

FIG. 18 is a block diagram illustrating an electronic system which includes the semiconductor devices illustrated in any of FIGS. 1, 4, 6, 8, 10 13 and 15 according to some embodiments of the present inventive concept.

FIGS. 19 and 20 illustrate an example semiconductor system to which the semiconductor devices illustrated in any of FIGS. 1, 4, 6, 8, 10 13 and 15 according to some embodiments of the present inventive concept may be applied.

FIGS. 21 to 28 are diagrams illustrating intermediate processes of methods for fabricating a semiconductor device according to some embodiments of the present inventive concept.

FIGS. 29 to 33 are diagrams illustrating intermediate processes of methods for fabricating a semiconductor device according to some embodiments of the present inventive concept.

### DETAILED DESCRIPTION

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of devices may be arranged in an array and/or in a two-dimensional pattern.

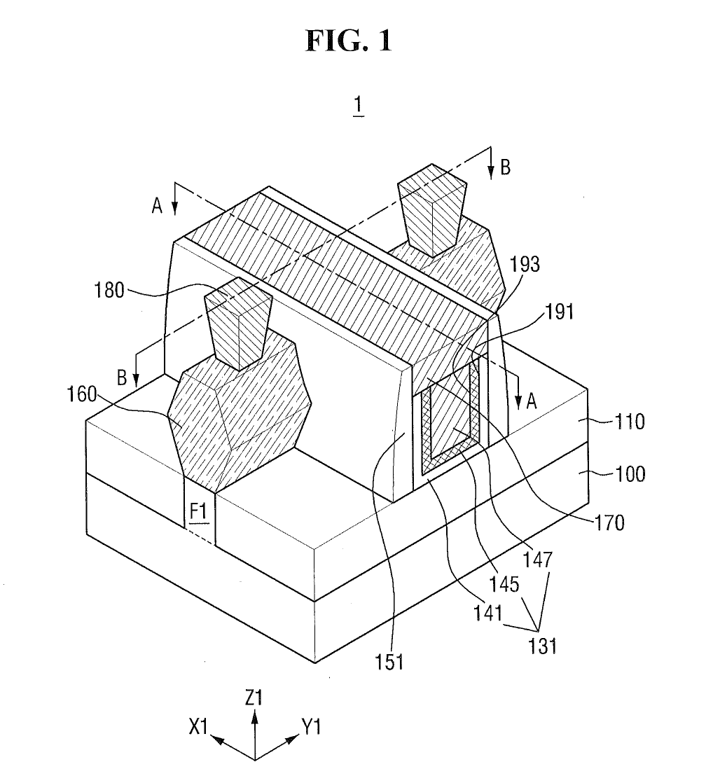

A semiconductor device 1 according to some embodiments of the present inventive concept will be described with reference to FIG. 1.

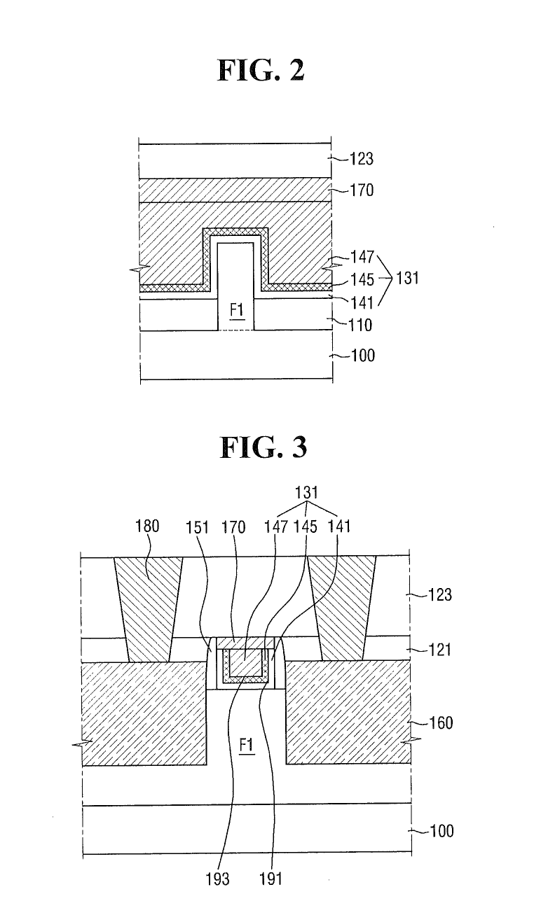

FIG. 1 is a perspective view illustrating a semiconductor device 1 according to some embodiments of the present inventive concept, FIG. 2 is a cross-sectional view of the semiconductor device 1 taken along line A-A of FIG. 1, and FIG. 3 is a cross-sectional view of the semiconductor device 1 taken along line B-B of FIG. 1. A first interlayer insulating layer 121 and a second interlayer insulating layer 123 will not be illustrated in FIG. 1 for the convenience of description.

Referring to FIGS. 1 to 3, the semiconductor device 1 according to the illustrated embodiments may include a substrate 100, a first fin F1, a device isolation layer 110, a first gate structure 131, a first source/drain 160, a first contact 180, the first interlayer insulating layer 121, and the second interlayer insulating layer 123.

Specifically, the substrate 100 may be formed of one or more semiconductor materials that are selected from a group consisting of Si, Ge, SiGe, GaP, GaAs, SiC, SiGeC, InAs, and/or InP. Further, a silicon on insulator (SOI) substrate may be used.

The first fin F1 may extend along a second direction Y1. Specifically, the first fin F1 may have a long side and a short side and the first fin F1 may extend in a direction of the long side. In FIG. 1, the direction of the long side is the second direction Y1 and a direction of the short side is a first direction X1, but the present inventive concept is not limited thereto. For example, in the first fin F1, the direction of the long side may be the first direction X1 and the direction of the short side may be the second direction Y2.

The first fin F1 may be a part of the substrate 100 or may include an epitaxial layer that is grown from the substrate 100. The first fin F1 may include, for example, Si and/or SiGe. The device isolation layer 110 is formed on the substrate 100 and may cover a side of the first fin F1. The device isolation layer 110 may be, for example, an oxide layer.

The first gate structure 131 may include a first gate insulating layer 141, a first work function adjusting layer 145, and a first gate metal 147 and may be formed on the first fin F1 so as to intersect the first fin F1. The first gate structure 131 may extend in the first direction X1.

A spacer 151 may be formed on a side wall of the first gate structure 131 and may include at least one of a nitride layer and an oxynitride layer. In the drawings, the spacer 151 is formed of a single layer but the present inventive concept is not limited thereto and the spacer 151 may be formed of multiple layers.

The first gate insulating layer 141 is formed on the first fin F1. The first gate insulating layer 141 may be formed between the first fin F1 and the first work function adjusting layer 145. As illustrated in FIG. 2, the first gate insulating layer 141 may be conformally formed above a top surface and a side of the first fin F1. Further, the first gate insulating layer 141 may be disposed between the first work function adjusting layer 142 and the device isolation layer 110. Such a first gate insulating layer 141 may include a high dielectric material having a dielectric constant that is higher than that of a silicon oxide layer. For example, the first gate insulating layer 141 may include HfO₂, ZrO₂, LaO, Al₂O₃, or Ta₂O₅.

Referring to FIG. 3, the first gate insulating layer 141 includes a first trench 191. The first gate insulating layer 141 is conformally formed along a side wall of the spacer 151 and the top surface of the first fin F1 so that the first trench 191 may be formed and the first work function adjusting layer 145 and the first gate metal 147 are disposed in the first trench 191.

The first work function adjusting layer 145 is formed on the first gate insulating layer 141. Specifically, the first work function adjusting layer 145 is conformally formed along the side wall and a bottom surface of the first trench 191, in the first trench 191. The first work function adjusting layer 145 is conformally formed so that a second trench 193 may be formed. Here, the second trench 193 is formed in the first trench 191 so that the second trench 193 is smaller than the first trench 191. The first work function adjusting layer 145 may function to adjust a work function of the first gate structure 131.

When the semiconductor device 1 according to the illustrated embodiments is an N type transistor, the first work function adjusting layer 145 may include a material selected from a group consisting of, for example, TiAl, TiAlC, TiAlN, TaC, TiC, and HfSi. When the semiconductor device 1 according to the illustrated embodiments is a P type transistor, the first work function adjusting layer 145 may include a material selected from a group consisting of, for example, Mo, Pd, Ru, Pt, TiN, WN, TaN, Ir, TaC, RuN, and/or MoN.

The first gate metal 147 may be formed on the work function adjusting layer 145. Specifically, the first gate metal 147 may fill the second trench 193, which is formed by the first work function adjusting layer 145. The first gate metal 147 may include, for example, W and/or Al.

As illustrated in FIG. 3, top surfaces of the first gate insulating layer 141, the first work function adjusting layer 145, and the first gate metal 147 may be disposed on the same plane.

In some embodiments, a first gate structure 131 may be formed by, for example, a replacement process, but the inventive concept is not so limited.

A first barrier layer 170 is formed on the first gate structure 131. The first barrier layer 170 may cover the top surface of the first work function adjusting layer 145 and may also additionally cover the top surfaces of the first gate insulating layer 141 and the first gate metal 147. At least one side wall of the first barrier layer 170 may be covered by the spacer 151.

The first barrier layer 170 may include the same material as the first gate metal 147 and thus the first barrier layer 170 may include W and/or Al. The first barrier layer 170 and the first gate metal 147 include the same material so that two layers may be considered as one layer. In this case, as illustrated in FIG. 3, a cross-section formed by the first barrier layer 170 and the first gate metal 147 may have a T shape.

The first source/drain 160 may be formed on the first fin F1 at both sides of the first gate structure 131. The first source/drain 160 may have an elevated source/drain shape. That is, a top surface of the first source/drain 160 may be higher than a bottom surface of the first interlayer insulating layer 121. Further, the first source/drain 160 and the first gate structure 131 may be insulated from each other by the spacer 151.

When the semiconductor device 1 according to some embodiments of the present inventive concept is the P type transistor, the first source/drain 160 may include a compressive stress material. For example, the compressive stress material may be a material having a higher lattice constant than Si, for example, SiGe. The compressive stress material may apply a compressive stress to the first fin F1 so as to improve mobility of a carrier of a channel region.

In contrast, when the semiconductor device 1 according to some embodiments of the present inventive concept is the N type transistor, the first source/drain 160 may include the same material as the substrate 100 or a tensile stress material. For example, when the substrate 100 is Si, the source/drain 160 may include Si or a material having a lower lattice constant than Si (for example, SiC).

The first source/drain 160 may have various shapes. For example, the first source/drain 160 may have at least one of a diamond shape and a circle. In the drawing, for example, the diamond shape (or a pentagonal shape or a hexagonal shape) is illustrated.

The first contact 180 may be formed on the first source/drain 160. The first contact 180 may electrically connect a wiring line and the first source/drain 160. The first contact 180 may be formed of a conductive material, and for example, the first contact 180 may include W, Al, and/or Cu, but the present inventive concepts are not limited thereto.

The first interlayer insulating layer 121 and the second interlayer insulating layer 123 may be sequentially formed on the device isolation layer 110. The first interlayer insulating layer 121 may cover the first source/drain 160 and a part of the side wall of the first contact 180. The second interlayer insulating layer 123 may cover the remaining side wall of the first contact 180.

As illustrated in FIG. 3, the top surface of the first interlayer insulating layer 121 may be parallel to a top surface of the first barrier layer 170. The first interlayer insulating layer 121 and the top surface of the first barrier layer 170 may be parallel to each other by a planarization process (for example, a CMP process). The second interlayer insulating layer 123 may be formed so as to cover the first barrier layer 170. The first interlayer insulating layer 121 and the second interlayer insulating layer 123 may include at least one of an oxide layer and an oxynitride layer.

The first barrier layer 170 prevents the first work function adjusting layer 145 and the second interlayer insulating layer 123 from being in contact with each other. The second interlayer insulating layer 123 includes an oxygen atom. When the second interlayer insulating layer 123 is in contact with the top surface of the first work function adjusting layer 145, the oxygen atom that is included in the second interlayer insulating layer 123 may be diffused onto the first work function adjusting layer 145. When the oxygen atom is diffused, the work function of the first work function adjusting layer 145 is increased so that a threshold voltage of the semiconductor device 1 is lowered. Specifically, when the first work function adjusting layer 145 includes TiN, a range of lowered threshold voltage may be larger than that of any other material. Therefore, in order to prevent the large range of the lowered threshold voltage, the first barrier layer 170 may be disposed between the second interlayer insulating layer 123 and the first gate structure 131.

Further, the material that is included in the first barrier layer 170 is a material having low resistivity so that a gate resistance may be lowered. A portion in which the first barrier layer 170 is formed is a portion occupied by the first gate structure 131. As will be described below, the first barrier layer 170 is formed on a portion, which is formed by partially etching an upper portion of the first gate structure 131. In this case, the first barrier layer 170 includes the same material as the first gate metal 147 and a resistivity of the material is lower than a resistivity of the first gate insulating layer 141 and a resistivity of the first work function adjusting layer 145. Accordingly, the resistance is reduced as much as the first gate insulating layer 141 and the first work function adjusting layer 145 are removed so that the gate resistance is reduced.

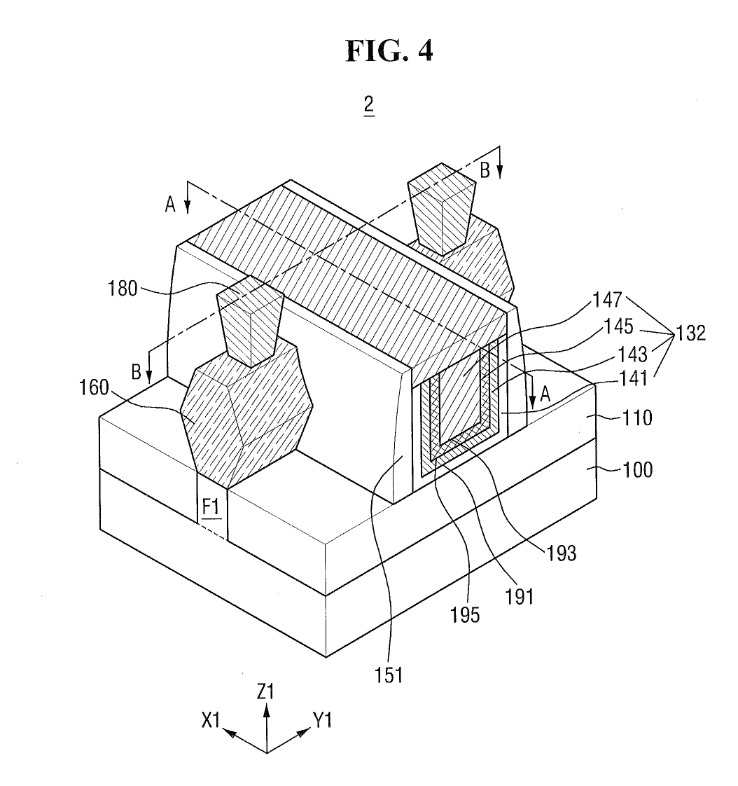

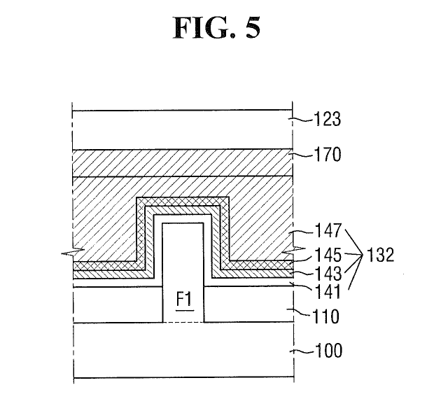

A semiconductor device 2 according to some embodiments of the present inventive concept will be described with reference to FIGS. 4 and 5. A description of a content duplicated with the content described above is omitted and a difference will be primarily described.

FIG. 4 is a perspective view illustrating a semiconductor device 2 according to some embodiments of the present inventive concept and FIG. 5 is a cross-sectional view of the semiconductor device 2 taken along line A-A of FIG. 4. A first interlayer insulating layer 121 and a second interlayer insulating layer 123 will not be illustrated in FIG. 4 for the convenience of description.

Unlike the semiconductor device 1 according to previously described embodiments, in the embodiments of the semiconductor device 2, a gate structure 132 may further include a second work function adjusting layer 143. Specifically, referring to FIGS. 4 and 5, the second work function adjusting layer 143 is disposed between a first gate insulating layer 141 and a first work function adjusting layer 145. The second work function adjusting layer 143 is conformally formed along a side wall and a top surface of a fin F1, as illustrated in FIG. 5, and may be formed in a first trench 191 that is formed by the first gate insulating layer 141. The second work function adjusting layer 143 includes a third trench 195. The first work function adjusting layer 145 is disposed in the third trench 195.

The first work function adjusting layer 145 may be an N type work function adjusting layer and the second work function adjusting layer 143 may be a P type work function adjusting layer. Therefore, the first work function adjusting layer 145 may include a material selected from a group consisting of, for example, TiAl, TiAlC, TiAlN, TaC, TiC, and/or HfSi and the second work function adjusting layer 143 may include a material selected from group consisting of, for example, Mo, Pd, Ru, Pt, TiN, WN, TaN, Ir, TaC, RuN, and/or MoN.

Even though the first work function adjusting layer 145 is formed on the second work function adjusting layer 143, the second work function adjusting layer 143 affects an operation characteristic of a transistor while the first work function adjusting layer 145 does not affect an operation characteristic of a transistor. Accordingly, embodiments of the semiconductor device 2 may be a P type transistor.

A first barrier layer 170 is formed on the gate structure 132 and may cover the first and second work function adjusting layers 143 and 145. The second interlayer insulating layer 123 is formed on the first barrier layer 170 and the second interlayer insulating layer 123 may be spaced apart from the gate structure 132 by the first barrier layer 170.

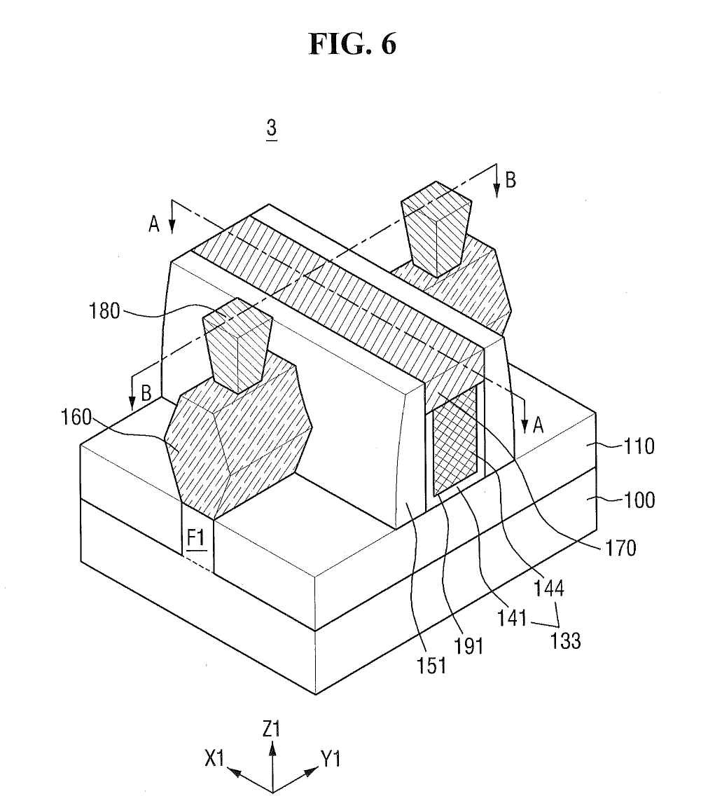

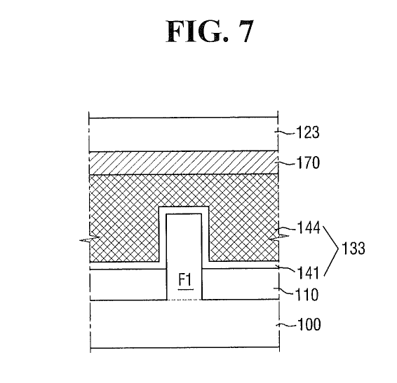

A semiconductor device 3 according to some embodiments of the present inventive concept will be described with reference to FIGS. 6 and 7. A description of a content duplicated with embodiments of semiconductor device 1 is omitted and a difference will be primarily described.

FIG. 6 is a perspective view illustrating a semiconductor device 3 according to some embodiments of the present inventive concept and FIG. 7 is a cross-sectional view of the semiconductor device 3 taken along line A-A of FIG. 6. A first interlayer insulating layer 121 and a second interlayer insulating layer 123 will not be illustrated in FIG. 6 for the convenience of description.

Unlike embodiments of the semiconductor device 1, in some embodiments of the semiconductor device 3, a gate structure 133 does not include a first gate metal 147. Specifically, a first gate insulating layer 141 including a first trench 191 is disposed and a first work function adjusting layer 144 is formed in the first trench 191. The first work function adjusting layer 144 may fill the first trench 191 and does not include a second trench 193.

A first barrier layer 170 covers the gate structure 133 and the second interlayer insulating layer 123 is formed on the first barrier layer 170. The first work function adjusting layer 144 and the second interlayer insulating layer 123 are not in contact with each other by the first barrier layer 170.

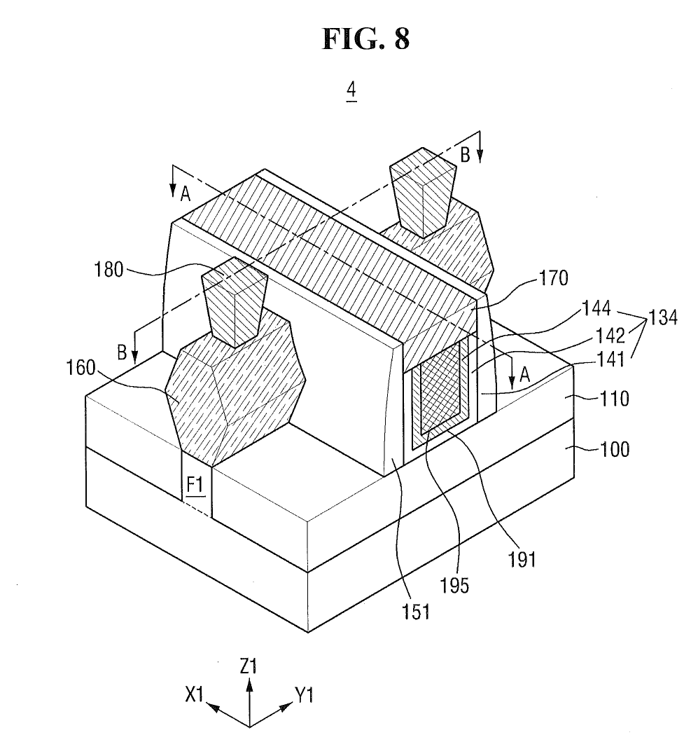

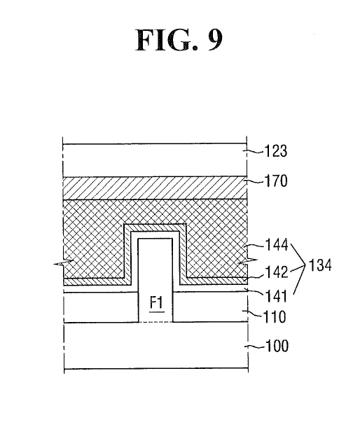

A semiconductor device 4 according to some embodiments of the present inventive concept will be described with reference to FIGS. 8 and 9. A description of a content duplicated with embodiments corresponding to semiconductor device 3 is omitted and a difference will be primarily described.

FIG. 8 is a perspective view illustrating a semiconductor device 4 according to some embodiments of the present inventive concept and FIG. 9 is a cross-sectional view of the semiconductor device 4 taken along line A-A of FIG. 8. A first interlayer insulating layer 121 and a second interlayer insulating layer 123 will not be illustrated in FIG. 8 for the convenience of description.

Unlike embodiments of the semiconductor device 3, in the semiconductor device 4 according to some embodiments of the present inventive concept, a gate structure 134 includes a second work function adjusting layer 142. Specifically, the second work function adjusting layer 142 is disposed between a first gate insulating layer 141 and a first work function adjusting layer 144. The first gate insulating layer 141 includes a first trench 191 and the second work function adjusting layer 142 is formed in the first trench 191. The second work function adjusting layer 142 may be conformally formed along a side wall and a top surface of a first fin F1, as illustrated in FIG. 9. The second work function adjusting layer 142 is conformally formed so as to include a third trench 195. The first work function adjusting layer 144 is disposed so as to fill the third trench 195. Similarly to embodiments of the semiconductor device 3, the semiconductor device 4 does not include a first gate metal 147.

Top surfaces of the first gate insulating layer 141, the second work function adjusting layer 142, and the first work function adjusting layer 144 may be disposed on the same plane. A first barrier layer 170 may cover the gate structure 134 and the second interlayer insulating layer 123 is formed on the first barrier layer 170. The second interlayer insulating layer 123 and the gate structure 134 are spaced apart from each other by the first barrier layer 170.

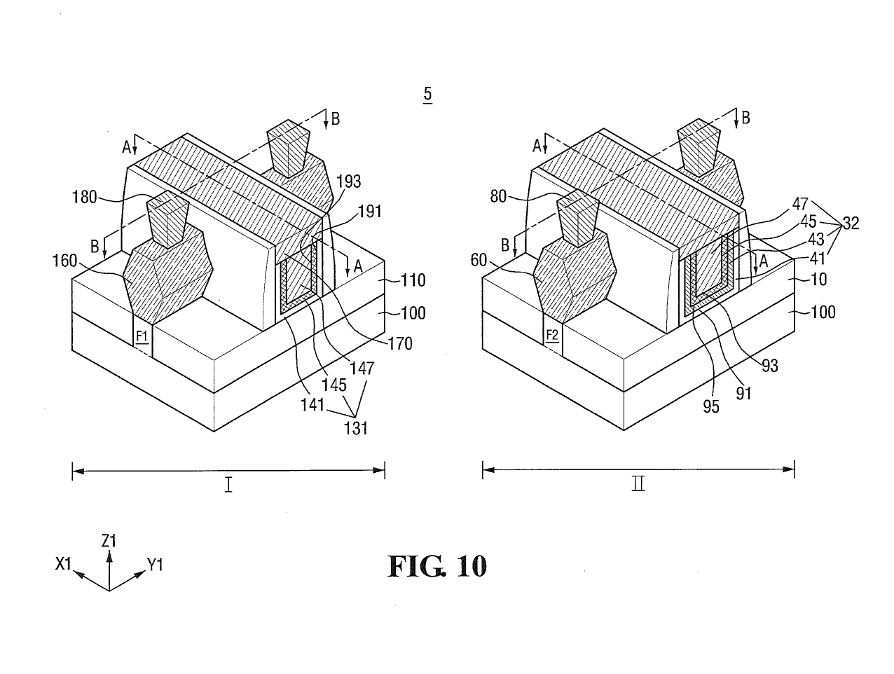

A semiconductor device 5 according to some embodiments of the present inventive concept will be described with reference to FIGS. 10 to 12. A description of a content duplicated with the content described above is omitted and a difference will be primarily described.

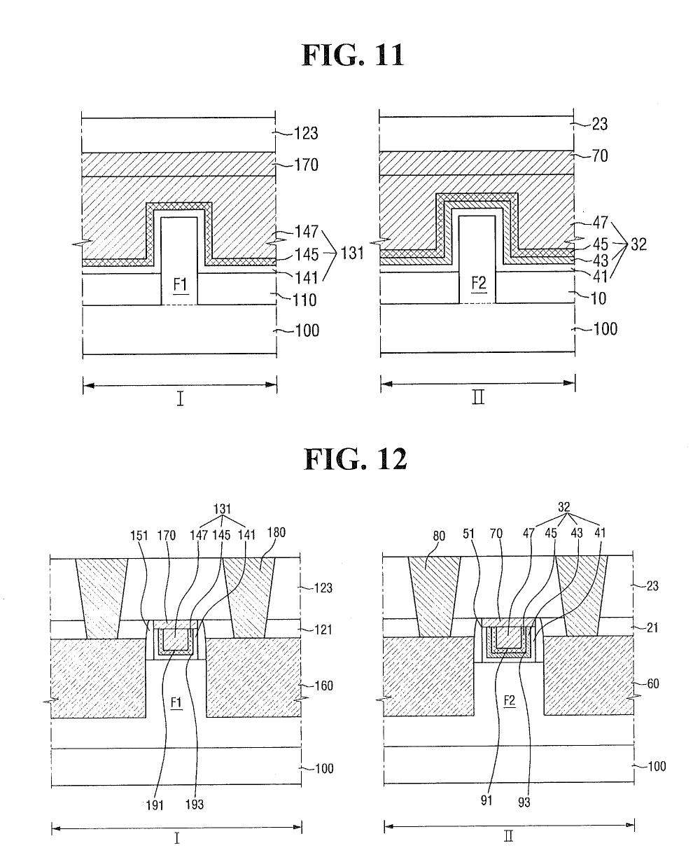

FIG. 10 is a perspective view illustrating a semiconductor device 5 according to some embodiments of the present inventive concept, FIG. 11 is a cross-sectional view of the semiconductor device 5 taken along line A-A of FIG. 10, and FIG. 12 is a cross-sectional view of the semiconductor device 5 taken along line B-B of FIG. 10. A first interlayer insulating layer 121 and a second interlayer insulating layer 123 will not be illustrated in FIG. 10 for the convenience of description.

In embodiments of semiconductor device 5, a substrate 100 includes a first region I and a second region II. The first region I and the second region II may be spaced apart from each other or connected to each other. A first fin F1 may be formed in the first region I and a second fin F2 may be formed in the second region II. Here, the first region I is the same as that described above regarding embodiments of the semiconductor device 1 and thus the description thereof will be omitted.

A second fin F2 is formed on the second region II. The second fin F2 may extend along a second direction Y1. Specifically, the second fin F2 may have a long side and a short side and the second fin F2 may extend in a direction of the long side. In FIG. 10, the direction of the long side is the second direction Y1 and a direction of the short side is a first direction X1, but the present inventive concept is not limited thereto. For example, in the second fin F2, the direction of the long side may be the first direction X1 and the direction of the short side may be the second direction Y2.

The second fin F2 may be a part of the substrate 100 or may include an epitaxial layer, which is grown from the substrate 100. The second fin F2 may include, for example, Si and/or SiGe. A device isolation layer 10 is formed on the substrate 100 and may cover a side of the second fin F2. The device isolation layer 10 may be, for example, an oxide layer.

A second gate structure 32 may include a second gate insulating layer 41, a third work function adjusting layer 43, a fourth work function adjusting layer 45, and a second gate metal 47 and may be formed on the second fin F2 so as to intersect the second fin F2. The second gate structure 32 may extend in the first direction X1.

A spacer 51 may be formed on a side wall of the second gate structure 32 and may include at least one of a nitride layer and an oxynitride layer. In the drawings, the spacer 51 is formed of a single layer but the present inventive concept is not limited thereto and the spacer 51 may be formed of multiple layers.

The second gate insulating layer 41 is formed on the second fin F2. The second gate insulating layer 41 may be formed between the second fin F2 and the second work function adjusting layer 45. As illustrated in FIG. 11, the second gate insulating layer 41 may be conformally formed above a top surface and a side of the second fin F2. Further, the second gate insulating layer 41 may be disposed between the third work function adjusting layer 42 and the device isolation layer 10. Such a second gate insulating layer 41 may include a high dielectric material having a dielectric constant that is higher than that of a silicon oxide layer. For example, the second gate insulating layer 41 may include HfO₂, ZrO₂, LaO, Al₂O₃, or Ta₂O₅.

Referring to FIG. 10, the second gate insulating layer 41 includes a fourth trench 91. The second gate insulating layer 41 is conformally formed along the side wall of the spacer 51 and the top surface of the second fin F2 so that the fourth trench 91 may be formed.

The third work function adjusting layer 43 is formed in the fourth trench 91. The third work function adjusting layer 43 may be conformally formed along a side wall and a top surface of the second fin F2 on the second gate insulating layer 41. The third work function adjusting layer 43 may include a fifth trench 95, as illustrated in FIG. 10.

The fourth work function adjusting layer 45 and the second gate metal 47 are disposed in the fifth trench 95. Specifically, the fourth work function adjusting layer 45 may be conformally formed along the third work function adjusting layer 43 and the fourth work function adjusting layer 45 forms a sixth trench 93.

The second gate metal 47 is formed so as to fill the sixth trench 93. The second gate metal 47 may include, for example, W and/or Al.

In the second gate structure 32, top surfaces of the second gate insulating layer 41, the third work function adjusting layer 43, the fourth work function adjusting layer 45, and the second gate metal 47 are disposed on the same plane and a second barrier layer 70 is formed on the top surfaces. The second interlayer insulating layer 23 and the gate structure 32 are spaced apart from each other by the first barrier layer 70 so as not to be in contact with each other. At least one side of the second barrier layer 70 may be covered by the spacer 51.

The second barrier layer 70 may include the same material as the second gate metal 47. Accordingly, a cross-section formed by the second gate metal 47 and the second barrier layer 70 may have a T shape, as illustrated in FIG. 10.

Here, an N type transistor may be formed in the first region I and a P type transistor may be formed in the second region II. Even though the fourth work function adjusting layer 45 is formed on the third work function adjusting layer 43, the third work function adjusting layer 43 affects an operation characteristic of a transistor but the fourth work function adjusting layer 45 does not affect an operation characteristic of a transistor. Accordingly, the first and fourth work function adjusting layers 145 and 45 may be an N type work function adjusting layer and the third work function adjusting layer 43 may be a P type work function adjusting layer. The first and fourth work function adjusting layers 145 and 45 may include a material selected from a group consisting of, for example, TiAl, TiAlC, TiAlN, TaC, TiC, and/or HfSi and the third work function adjusting layer 43 may include a material selected from a group consisting of, for example, Mo, Pd, Ru, Pt, TiN, WN, TaN, Ir, TaC, RuN, and/or MoN.

A second source/drain 60 may be formed on the second fin F2 at both sides of the second gate structure 32. The second source/drain 60 may have an elevated source/drain shape. That is, a top source of the second source/drain 60 may be higher than a bottom surface of the first interlayer insulating layer 121. Further, the second source/drain 60 and the second gate structure 32 may be insulated from each other by the spacer 51.

An N type transistor is formed in the first region I in the semiconductor device 5 according to some embodiments of the present inventive concept so that the first source/drain 160 may include the same material as the substrate 100 or a tensile stress material. For example, when the substrate 100 is Si, the first source/drain 160 may be Si or a material having a lower lattice constant than Si (for example, SiC).

A PMOS transistor is formed in the second region II so that the second source/drain 60 may include a compressive stress material. For example, the compressive stress material may be a material having a higher lattice constant than Si, for example, SiGe. The compressive stress material may apply a compressive stress to the second fin F2 so as to improve mobility of a carrier of a channel region.

The second source/drain 60 may have various shapes. For example, the second source/drain 60 may have at least one of a diamond shape and a circle. In the drawing, for example, the diamond shape (or a pentagonal shape or a hexagonal shape) is illustrated.

A second contact 80 may be formed on the second source/drain 60. The second contact 80 may electrically connect a wiring line and the second source/drain 60. The second contact 80 may be formed of a conductive material, and for example, the second contact 80 may include W, Al, and/or Cu, but the present inventive concept is not limited thereto.

The first interlayer insulating layer 21 and the second interlayer insulating layer 23 are sequentially formed on the device isolation layer 10. The first interlayer insulating layer 21 may cover the second source/drain 60 and a part of the side wall of the second contact 80. The second interlayer insulating layer 23 may cover the remaining side wall of the second contact 80.

As illustrated in FIG. 10, the top surface of the first interlayer insulating layer 21 may be parallel to a top surface of the second barrier layer 70. The first interlayer insulating layer 21 and the top surface of the second barrier layer 70 may be parallel to each other by a planarization process (for example, a CMP process). The second interlayer insulating layer 23 may be formed so as to cover the second barrier layer 70. The first interlayer insulating layer 21 and the second interlayer insulating layer 23 may include at least one of an oxide layer and/or an oxynitride layer.

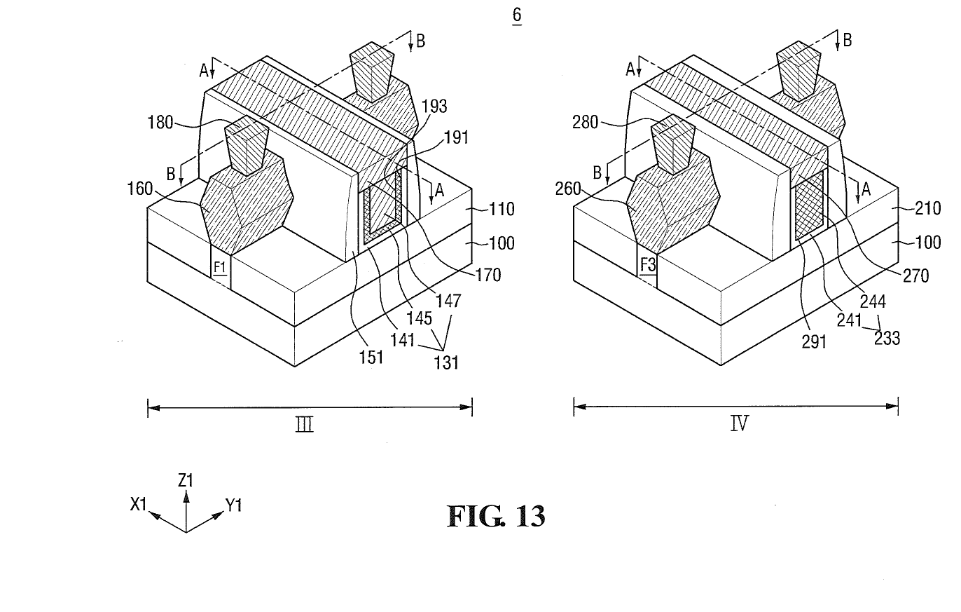

A semiconductor device 6 according to some embodiments of the present inventive concept will be described with reference to FIGS. 13 to 15. A description of a content duplicated with the content described above will be omitted.

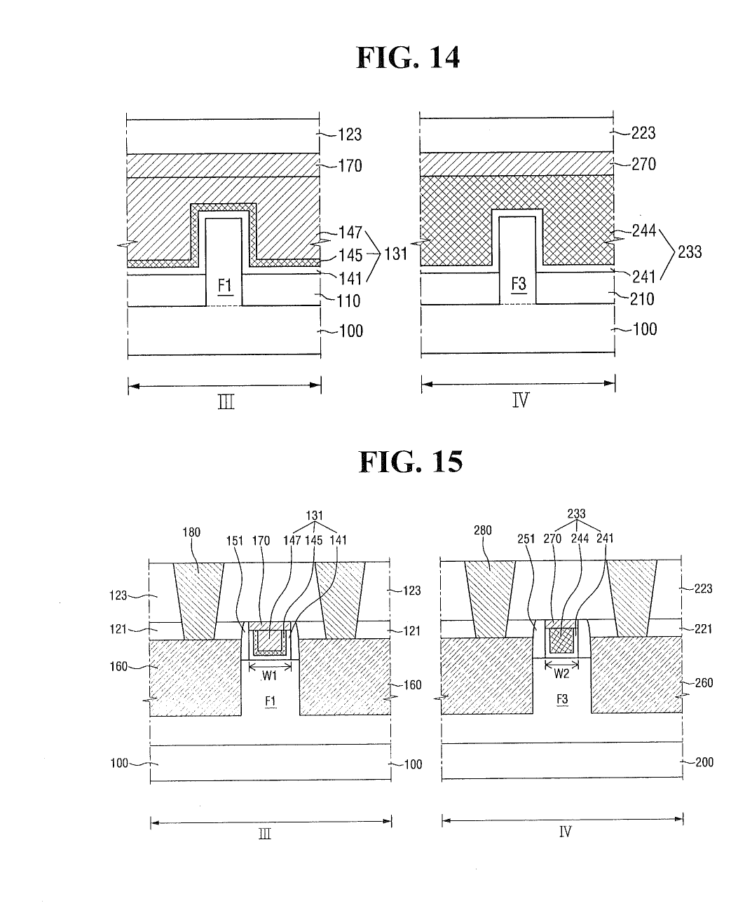

FIG. 13 is a perspective view illustrating a semiconductor device 6 according to some embodiments of the present inventive concept, FIG. 14 is a cross-sectional view of the semiconductor device 6 taken along line A-A of FIG. 13, and FIG. 15 is a cross-sectional view of the semiconductor device 6 taken along line B-B of FIG. 13. A first interlayer insulating layer 21 and a second interlayer insulating layer 23 will not be illustrated in FIG. 13 for the convenience of description.

In some embodiments of the semiconductor device 6, a substrate 100 includes a third region III and a fourth region IV. The third region III is the same as that in embodiments corresponding to the semiconductor device 1 described above. Therefore, description for the third region III will be omitted. The fourth region IV corresponds to embodiments of semiconductor device 3 as described above and the first fin F1, the first device isolation layer 110, the first source/drain 160, the first contact 180, the gate structure 133, the first gate insulating layer 141, the first work function adjusting layer 144, the spacer 151, the first and second interlayer insulating layers 121 and 123, and the first barrier layer 170 in FIG. 6 correspond to the third fin F3, the third device isolation layer 210, the third source/drain 260, the third contact 280, the third gate structure 233, the third gate insulating layer 241, the fifth work function adjusting layer 244, the third spacer 251, the third and fourth interlayer insulating layers 221 and 223, and the third barrier layer 270 in FIG. 13, respectively.

A width W1 of the first gate structure 131 is different from a width W2 of the third gate structure 233. Specifically, the width W1 of the first gate structure 131 is larger than the width W2 of the third gate structure 233. The width W1 of the first gate structure 131 is large so that the first work function adjusting layer 145 may form the second trench 193 and the first gate metal 147 may fill the second trench 193. In contrast, the width W2 of the third gate structure 233 is small so that the fifth work function adjusting layer 244 is not conformally formed and thus the fifth work function adjusting layer 244 may not form a trench and fill a sixth trench 291 that is included in the third gate insulating layer 241. Accordingly, the third gate structure 233 may include the third gate adjusting layer 241 and the fifth work function adjusting layer 244.

The third region III and the fourth region IV may be spaced apart from each other or connected to each other. The fourth region IV may be a region in which a transistor having a low threshold voltage and a high switching speed is formed and the third region III may be a region in which a transistor that has a high threshold voltage and a low switching speed, but has high reliability is formed. For example, the fourth region IV may be a cell array region in which a cell array in which unit memory cells are grouped in a matrix is formed and the third region III may be a core/peripheral region in which a peripheral circuit, which loads external data into the cell array and loads data of the cell array to the outside is complexly formed, but the present inventive concept is not limited thereto.

In some embodiments, the fourth region IV may be an SRAM region and the third region III may be a logic region. However, the present inventive concept is not limited thereto, and the third region III may be a logic region and the fourth region IV may be a region (for example, a DRAM, an MRAM, an RRAM, and/or a PRAM) in which another memory is formed.

The transistor that is formed in the third region III and the fourth region IV may be, for example, a PMOS transistor.

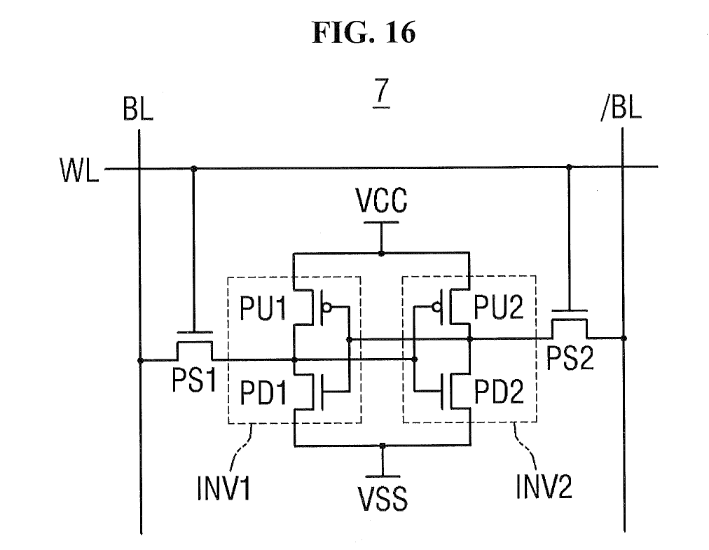

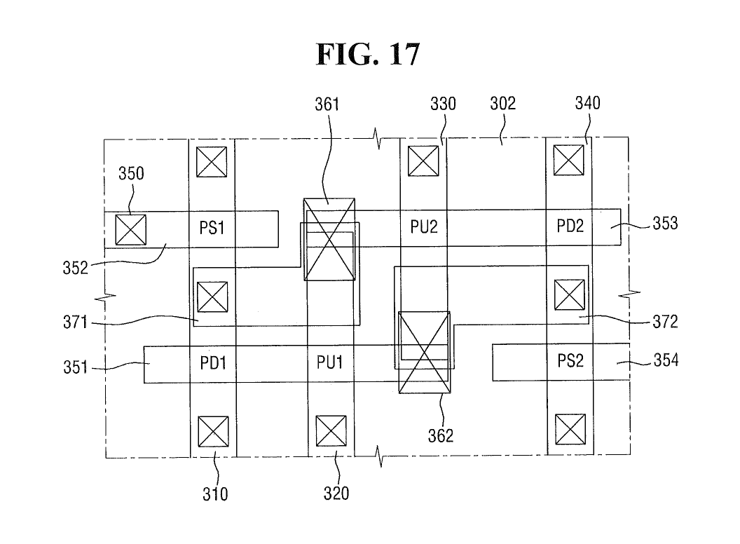

A semiconductor device 7 according to some embodiments of the present inventive concept will be described with reference to FIGS. 16 and 17.

FIGS. 16 and 17 are a circuit diagram and a layout diagram illustrating a semiconductor device 7 according to some embodiments of the present inventive concept, respectively. Embodiments of semiconductor device 7 may be applied to all devices that are configured by a general logic device that uses a fin type transistor, but FIGS. 16 and 17 illustrate an SRAM as an example.

First, referring to FIG. 16, the semiconductor device 7 may include a pair of inverters INV1 and INV2, which are connected in parallel between a power node Vcc and a ground node Vss, and a first pass transistor PS1 and a second pass transistor PS2, which are connected to output nodes of the inverters INV1 and INV2, respectively. The first pass transistor PS1 and the second pass transistor PS2 may be connected with a bit line BL and a complementary bit line/BL, respectively. Gates of the first pass transistor PS1 and the second pass transistor PS2 may be connected to a word line WL.

The first inverter INV1 includes a first pull-up transistor PU1 and a first pull-down transistor PD1 that are connected in series and the second inverter INV2 includes a second pull-up transistor PU2 and a second pull-down transistor PD2 that are connected in series. The first pull-up transistor PU1 and the second pull-up transistor PU2 may be PMOS transistors and the first pull-down transistor PD1 and the second pull-down transistor PD2 may be NMOS transistors.

The first inverter INV1 and the second inverter INV2 may be configured such that an input node of the first inverter INV1 is connected to an output node of the second inverter INV2 and an input node of the second inverter INV2 is connected to an output node of the first inverter INV1 in order to configure one latch circuit.

Here, referring to FIGS. 16 and 17, a first fin 310, a second fin 320, a third fin 330, and a fourth fin 340, which are spaced apart from each other, are formed to extend in one direction (for example, a vertical direction of FIG. 16). Extended lengths of the second fin 320 and the third fin 330 may be shorter than those of the first fin 310 and the fourth fin 340.

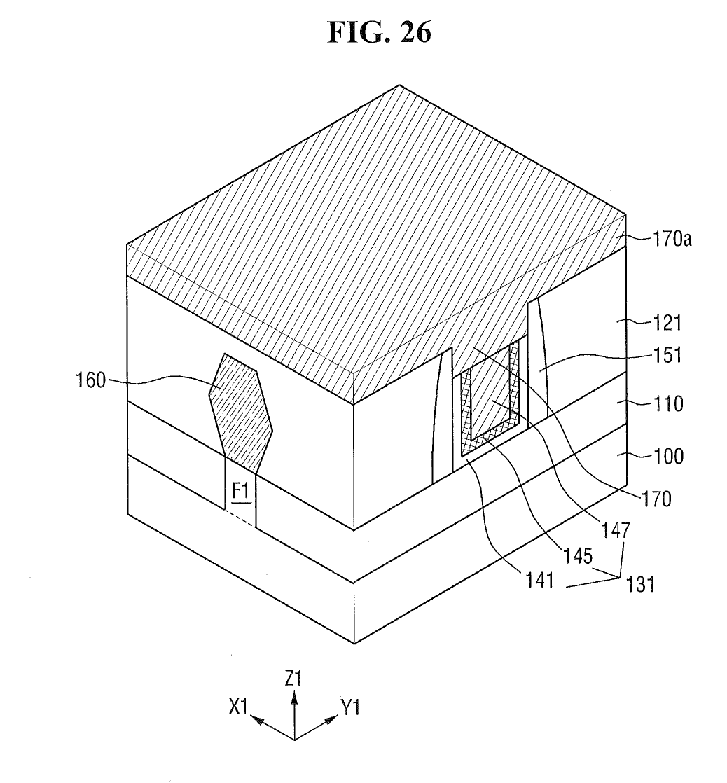

Further, a first gate electrode 351, a second gate electrode 352, a third gate electrode 353, and a fourth gate electrode 354 extend in another direction (for example, a horizontal direction of FIG. 26) and formed so as to intersect the first fin 310 to the fourth fin 340. Specifically, the first gate electrode 351 may completely intersect the first fin 310 and the second fin 320 and partially overlap an end of the third fin 330. The third gate electrode 353 may completely intersect the fourth fin 340 and the third fin 330 and partially overlap an end of the second fin 320. The second gate electrode 352 and the fourth gate electrode 354 are formed to intersect the first fin 310 and the fourth fin 340, respectively.

As illustrated in the drawing, the first pull-up transistor PU1 is defined around a region where the first gate electrode 351 intersects the second fin 320, the first pull-down transistor PD1 is defined around a region where the first gate electrode 351 intersects the first fin 310, and the first pass transistor PS1 is defined around a region where the second gate electrode 352 intersects the first fin 310. The second pull-up transistor PU2 is defined around a region where the third gate electrode 353 intersects the third fin 330, the second pull-down transistor PD2 is defined around a region where the third gate electrode 353 intersects the fourth fin 340, and the second pass transistor PS2 is defined around a region where the fourth gate electrode 354 intersects the fourth fin 340.

Even though not specifically illustrated, a recess may be formed on both sides of a region where the first to fourth gate electrodes 351 to 354 and the first to fourth fins 310, 320, 330, and 340 intersect and a source/drain may be formed in the recess.

Further, a plurality of contacts 350 may be formed.

Further, a shared contact 361 simultaneously connects the second fin 320, the third gate line 353, and a wiring line 371. The shared contact 362 simultaneously connects the third fin 330, the first gate line 351, and a wiring line 372.

The first pull-up transistor PU1, the second pull-up transistor PU2, the first pull-down transistor PD1, and the second pull-down transistor PD2 may be implemented by a fin type transistor, that is, the above-described semiconductor devices 1 to 6 and have the configurations described above with reference to FIGS. 1, 4, 6, 8, 10, and 13.

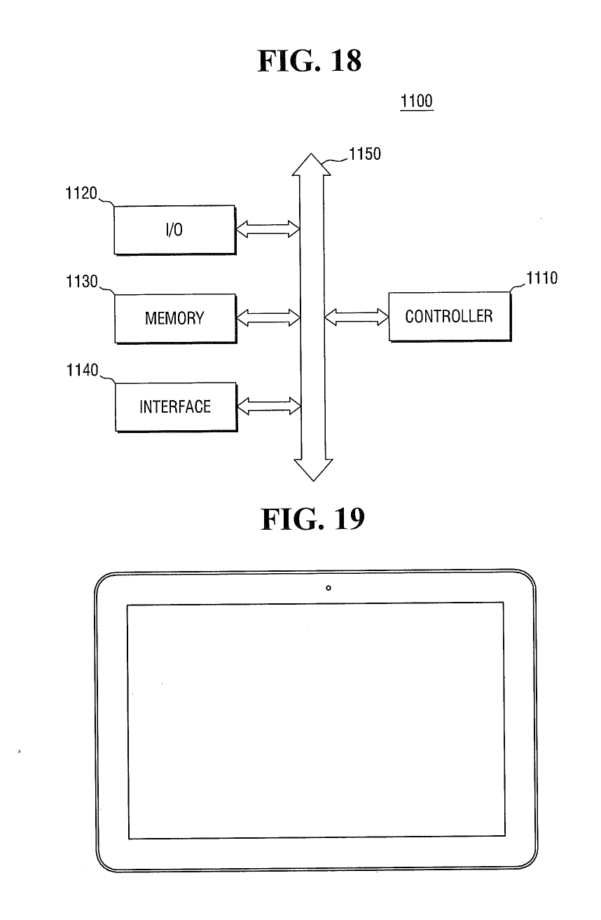

FIG. 18 is a block diagram illustrating an electronic system that includes the semiconductor devices 1 to 7 according to some embodiments of the present inventive concept.

Referring to FIG. 18, an electronic system 1100 according to some embodiments of the present inventive concept may include a controller 1110, an input/output device (I/O) 1120, a memory device 1130, an interface 1140, and a bus 1150. The controller 1110, the input/output device 1120, the memory device 1130, and/or the interface 1140 may be coupled to each other through the bus 1150. The bus 1150 corresponds to a path through which data moves.

The controller 1110 may include at least one of a microprocessor, a digital signal process, a micro controller, and logical elements that may perform a similar function to the above-mentioned devices. The input/output device 1120 may include a keypad, a keyboard, and/or a display device. The memory device 1130 may store data and/or a command language. The interface 1140 may function to transmit data to a communication network and/or receive data from the communication network. The interface 1140 may be a wired and/or wireless type. For example, the interface 1140 may include an antenna and/or a wired and/or wireless transceiver. Even though not illustrated, the electronic system 1100 may further include a high speed DRAM and/or SRAM as an operation memory, which may improve an operation of the controller 1110. The semiconductor devices 1 to 7 according to some embodiments of the present inventive concept may be provided in the memory device 1130 and/or provided as a part of the controller 1110 and/or the input/output device (I/O) 1120.

The electronic system 1100 may be applied to a personal digital assistant (PDA), a portable computer, a web tablet, a wireless phone, a mobile phone, a digital music player, a memory card, and/or all kinds of electronic products that may transmit and/or receive information under a wireless environment.

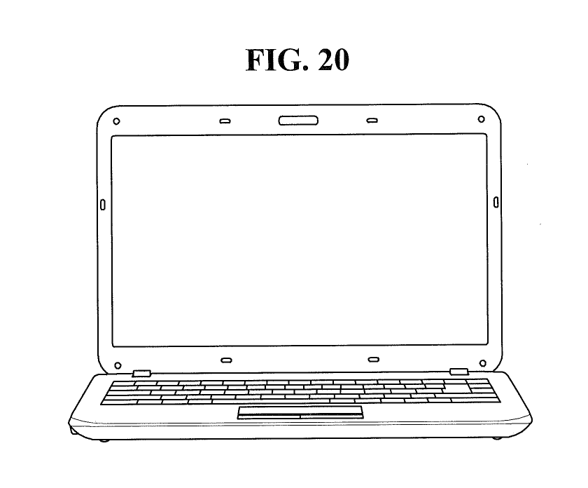

FIGS. 19 and 20 illustrate an example semiconductor system to which the semiconductor devices 1 to 7 according to some embodiments of the present inventive concept may be applied. FIG. 19 illustrates a tablet PC and FIG. 20 illustrates a notebook computer. The semiconductor devices 1 to 7 according to some embodiments of the present inventive concept may be used for a tablet PC and/or a notebook computer. The semiconductor devices 1 to 7 according to some embodiments of the present inventive concept may be applied to other integrated circuit devices that have not been exemplified.

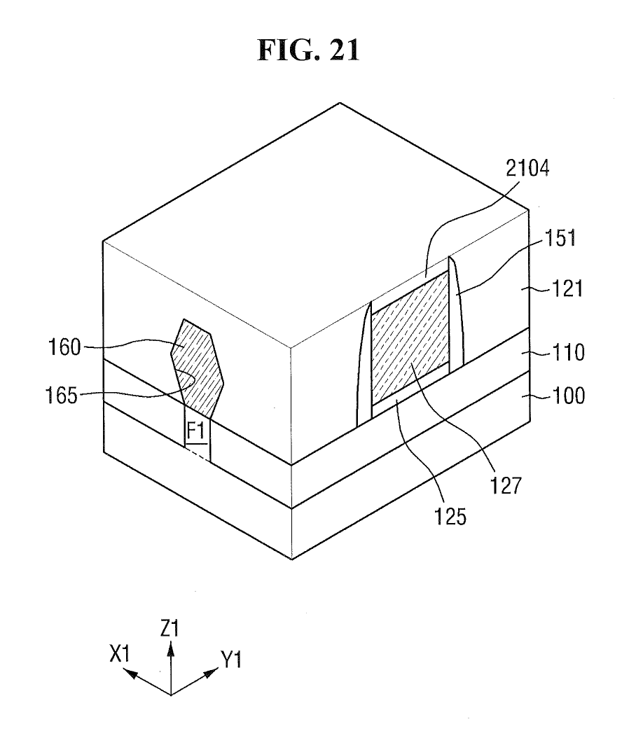

Methods for fabricating a semiconductor device according to some embodiments of the present inventive concept will be described with reference to FIGS. 21 to 28. A description of a content duplicated with the content described above will be omitted.

FIGS. 21 to 28 are diagrams illustrating intermediate processes of a method for fabricating a semiconductor device 1 according to some embodiments of the present inventive concept.

Referring to FIG. 21, a first fin F1 is formed on a substrate 100. In FIG. 21, the first fin F1 extends along a second direction Y1, but the present inventive concept is not limited thereto and the first fin F1 may extend in a first direction X1. A device isolation layer 110 is formed on the substrate 100 so as to cover a part of a side wall of the first fin F1. The device isolation layer 110 may be formed of a material including at least one of a silicon oxide layer, a silicon nitride layer, and/or a silicon oxynitride layer.

In some embodiments, a part of the first fin F1, which protrudes over the device isolation layer 110, may be formed by an epitaxial process. Specifically, after forming the device isolation layer 110, a part of the first fin F1 may be formed by the epitaxial process that uses a top surface of the first fin F1, which is exposed by the device isolation layer 110, as a seed without performing a recess process.

A doping process for adjusting a threshold voltage may be performed on the first fin F1. Phosphorous (P) and/or arsenic (As) may be used as an impurity in order to form a P type transistor. Boron (B) may be used as an impurity in order to form an N type transistor.

A dummy gate structure intersects the first fin F1 to extend in the first direction X1. The dummy gate structure may be formed by sequentially laminating a dummy gate insulating layer 125, a dummy gate electrode 127, and a mask pattern 2104. For example, the dummy gate insulating layer 125 may be a silicon oxide layer and the dummy gate electrode 127 may be polysilicon. A spacer 151 is formed on a side wall of the dummy gate structure. The spacer 151 may be a silicon nitride layer and/or a silicon oxynitride layer.

A recess 165 may be formed by removing a part of the first fin F1 that is exposed at both sides of the dummy gate electrode 127.

An elevated first source/drain 160 is formed in the recess 165 and may be formed by an epitaxial process. Depending on whether a semiconductor device to be formed is an N type transistor or a P type transistor, a material for the elevated first source/drain 160 may vary. If necessary, the impurity may be in-situ doped during the epitaxial process.

In FIG. 21, the elevated first source/drain 160 has a diamond shape (or a pentagonal shape or a hexagonal shape), but the present inventive concept is not limited thereto, and for example, the elevated first source/drain 160 may have at least one of a circular shape, a rectangular shape and an elliptical shape.

A first interlayer insulating layer 121 that covers the elevated first source/drain 160 is formed. The first interlayer insulating layer 121 may be, for example, at least one of an oxide layer and/or an oxynitride layer.

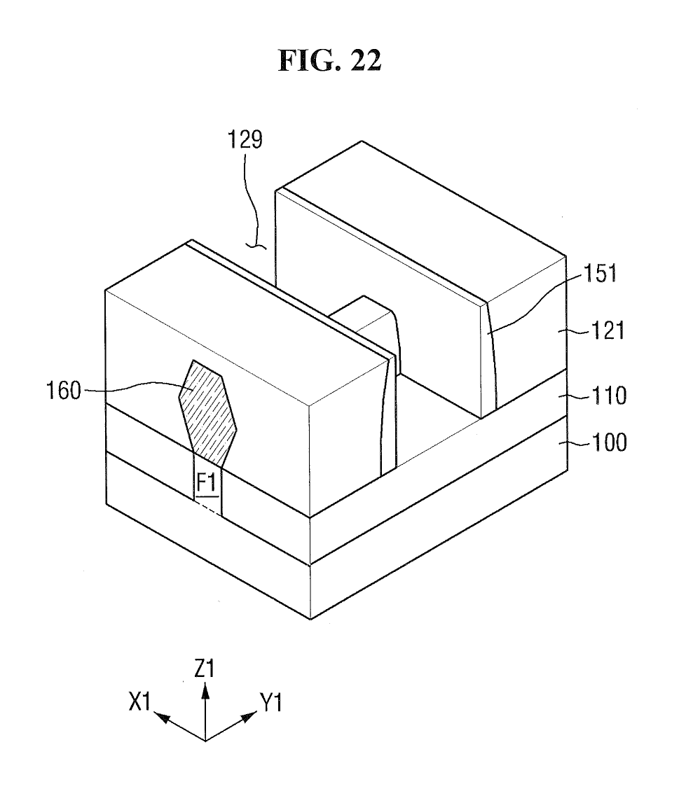

Referring to FIG. 22, the dummy gate structure is removed to expose the first fin F1. For example, the first interlayer insulating layer 121 may be planarized until a top surface of the dummy gate electrode 127 is exposed. As a result, the mask pattern 2104 is removed and the top surface of the dummy gate electrode 127 may be exposed.

Next, the dummy gate electrode 127 and the dummy gate insulating layer 125 are sequentially removed. When the dummy gate electrode 127 and the dummy gate insulating layer 125 are removed, a trench 129 through which the device isolation layer 110 is exposed is formed and the first fin F1 is exposed as illustrated in FIG. 22.

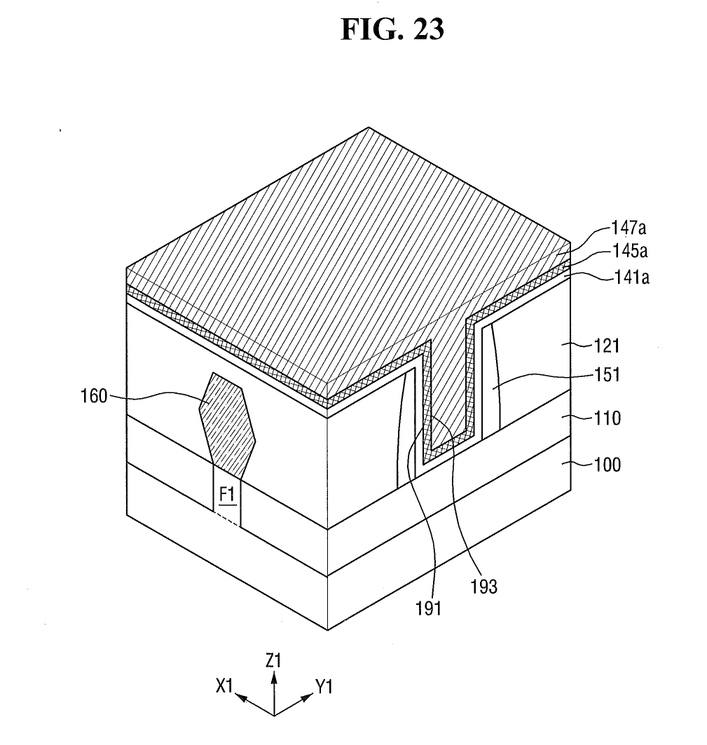

Referring to FIG. 23, a first gate insulating layer 141a is formed on the exposed first fin F1. The first gate insulating layer 141a may be substantially conformally formed along a side wall and a bottom surface of the trench 129. The first gate insulating layer 141a forms a first trench 191 in the trench 129.

Next, a first work function adjusting layer 145a is formed on the first gate insulating layer 141a. The first work function adjusting layer 145a may be conformally formed along the side wall and the bottom surface of the first trench 191. The first work function adjusting layer 145a forms a second trench 193 in the first trench 191.

Next, a first gate metal 147a is formed on the first work function adjusting layer 145a. The first gate metal 147a may fill a second trench 193.

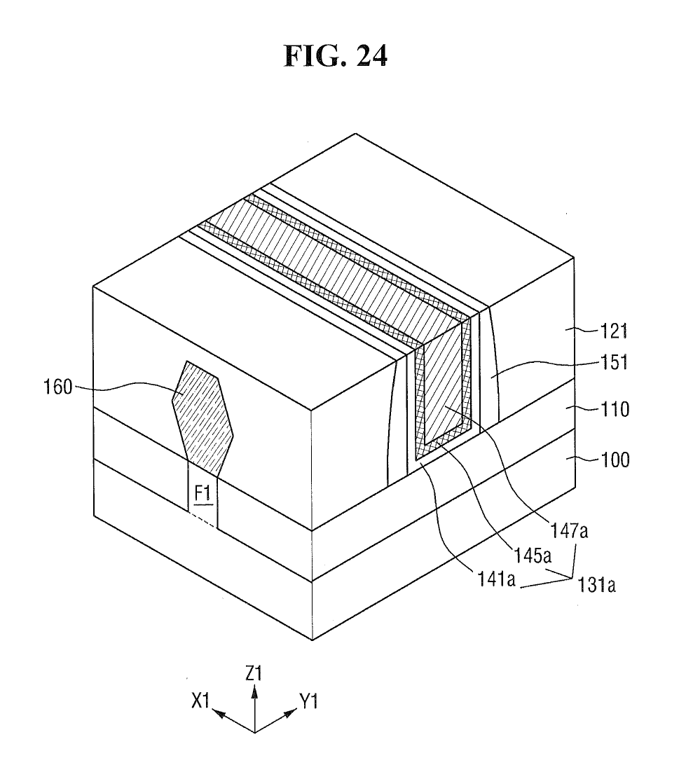

Referring to FIG. 24, a chemical mechanical polishing (CMP) process is performed until the first interlayer insulating layer 121 is exposed. By doing this, a gate structure 131a may be formed in the trench 129.

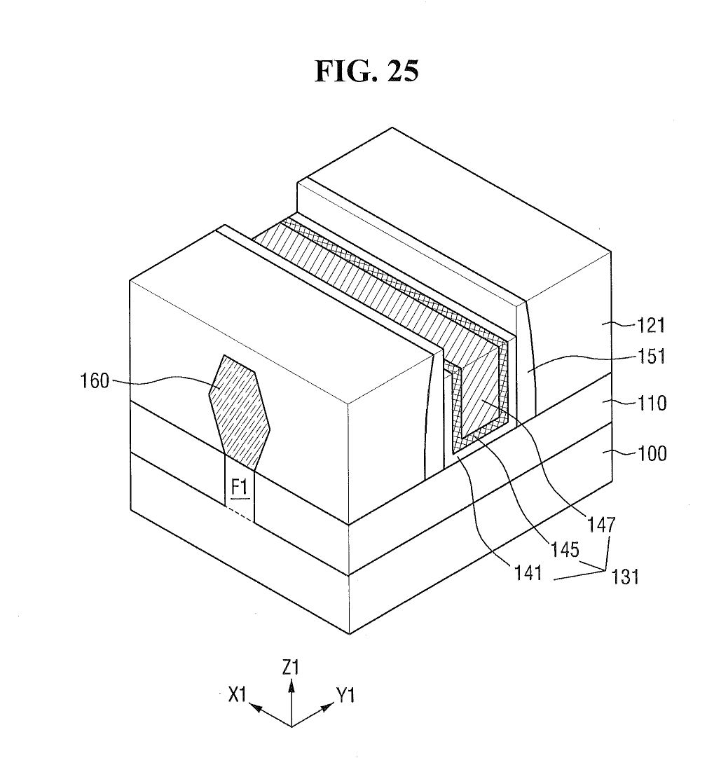

Referring to FIG. 25, a top portion of the gate structure 131a is partially etched. The top portion of the gate structure 131a may be partially etched using at least one of a dry etching process and/or a wet etching process.

Referring to FIG. 26, a first barrier layer 170a is formed such that the gate structure 131a fills an etched portion in the trench 129. The first barrier layer 170a may cover the first gate insulating layer 141, the first work function adjusting layer 145, and/or the first gate metal 147.

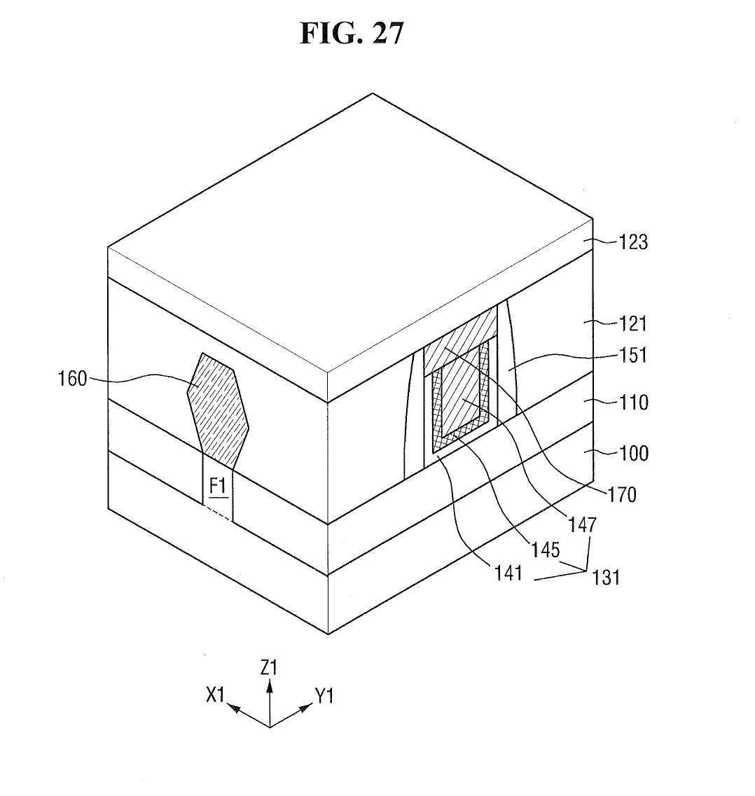

Referring to FIG. 27, the CMP process is performed again in order to expose the first interlayer insulating layer 121. By doing this, the first barrier layer 170 is disposed only in the trench 129.

Next, a second interlayer insulating layer 123 is formed on the first interlayer insulating layer 121. The second interlayer insulating layer 123 may cover the first barrier layer 170. The gate structure 131 is not in contact with the second interlayer insulating layer 123 due to the first barrier layer 170.

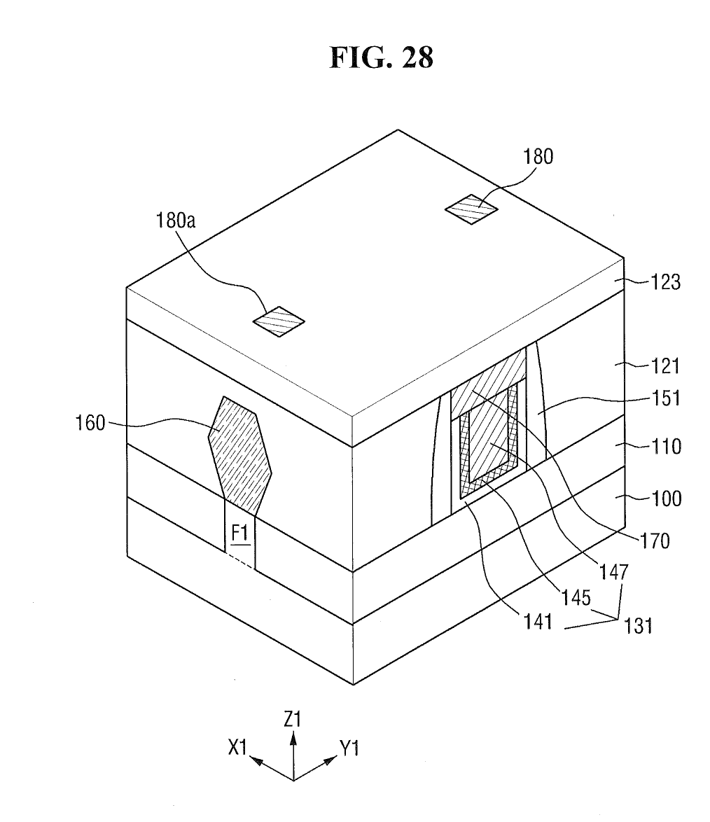

Referring to FIG. 28, a contact hole 180a that passes through the first and the second interlayer insulating layers 121 and 123 is formed on the elevated first source/drain 160 so as to expose the top surface of the elevated first source/drain 160. After forming the contact hole 180a, a first contact 180 is formed in the contact hole 180a. When the first and second interlayer insulating layers 121 and 123 of FIG. 28 are omitted, FIG. 28 may be the same as FIG. 1.

Methods for fabricating a semiconductor device 2 according to some embodiments of the present inventive concept will be described with reference to FIGS. 21, 22 and 29 to 33. A description of a content duplicated with the content described above will be omitted

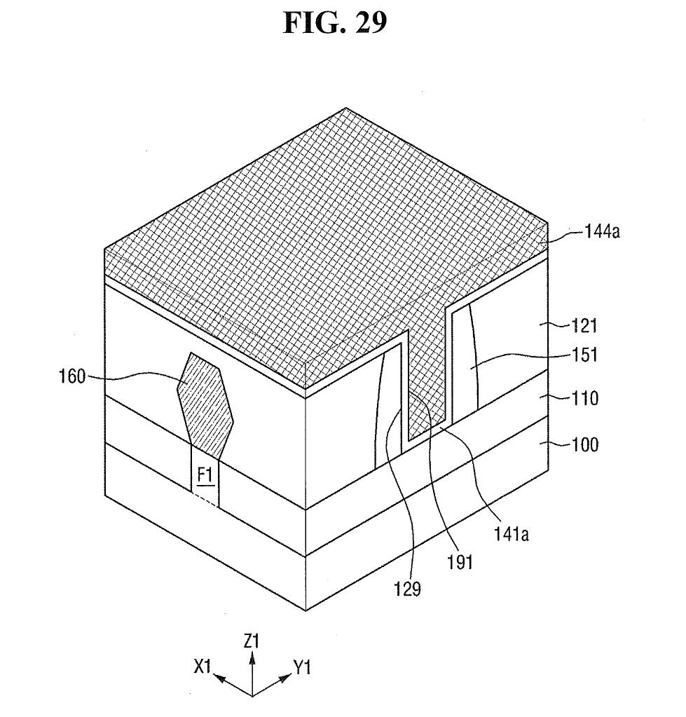

FIGS. 29 to 33 are diagrams illustrating intermediate processes of methods for fabricating a semiconductor device 2 according to some embodiments of the present inventive concept.

FIGS. 21 and 22 are same as the method for fabricating a semiconductor device 1 according to some embodiments of the present inventive concept and thus description thereof will be omitted.

Referring to FIG. 29, a first gate insulating layer 141a is formed on the exposed first fin F1. The first gate insulating layer 141a may be substantially conformally formed along a side wall and a bottom surface of a trench 129. The first gate insulating layer 141a forms a first trench 191 in the trench 129.

Next, a first work function adjusting layer 144a is formed on the first gate insulating layer 141a. The first work function adjusting layer 144a is formed so as to fill the first trench 191. Therefore, unlike the method for fabricating embodiments of a semiconductor device 1, in the methods for fabricating a semiconductor device 2, a first gate metal 147 is not formed in the trench 129.

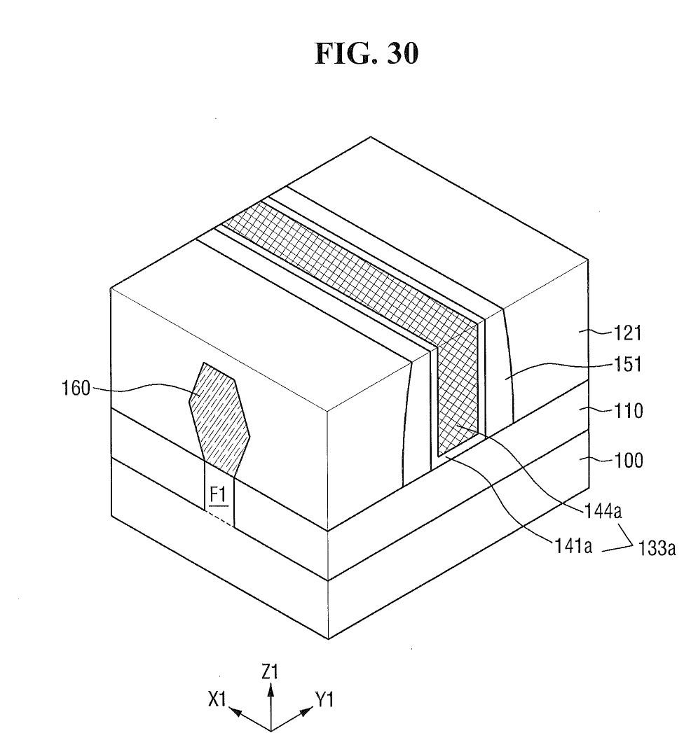

Referring to FIG. 30, a chemical mechanical polishing (CMP) process is performed until a first interlayer insulating layer 121 is exposed. By doing this, a gate structure 133a may be formed in the trench 129.

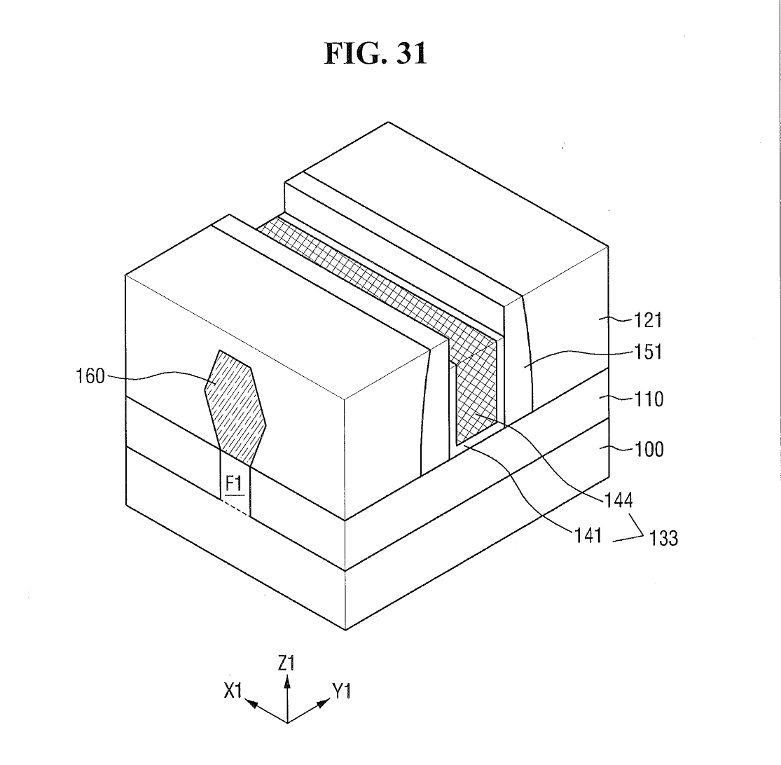

Referring to FIG. 31, a top portion of the gate structure 133a is partially etched. The top portion of the gate structure 133a may be partially etched using at least one of a dry etching process and/or a wet etching process.

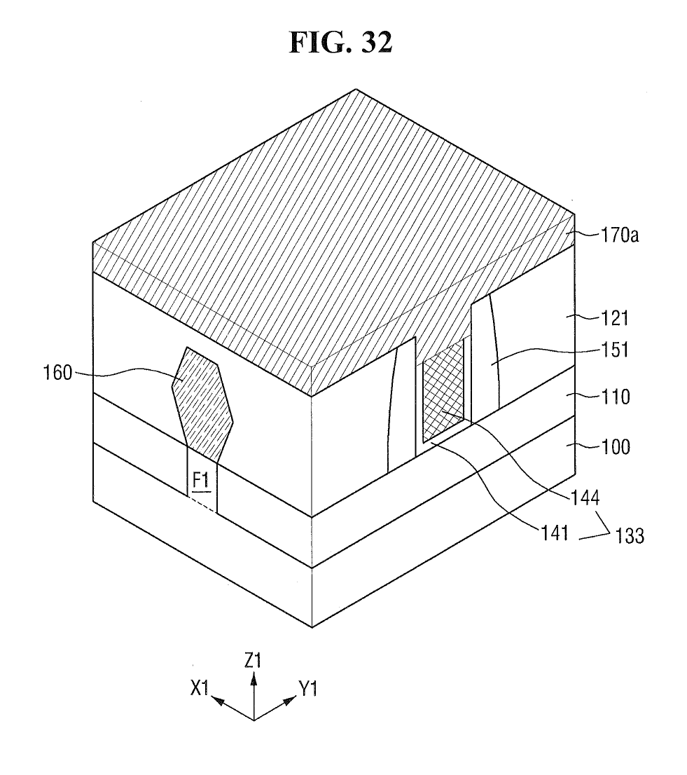

Referring to FIG. 32, a first barrier layer 170a is formed such that the gate structure 133a in the trench 129 fills an etched portion. The first barrier layer 170a may cover the first gate insulating layer 141 and/or the first work function adjusting layer 144.

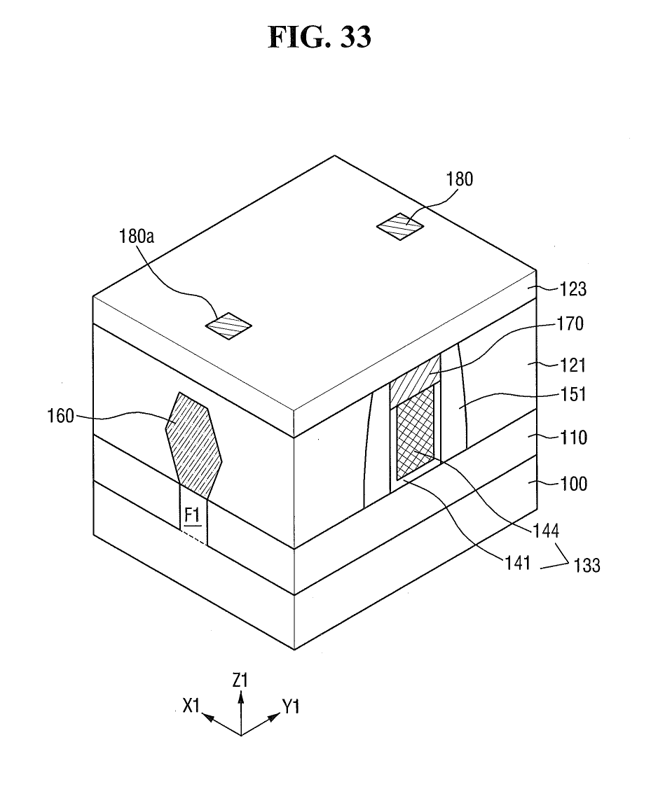

Referring to FIG. 33, the CMP process is performed again in order to expose the first interlayer insulating layer 121. By doing this, the first barrier layer 170 is disposed only in the trench 129.

Next, a second interlayer insulating layer 123 is formed on the first interlayer insulating layer 121. The second interlayer insulating layer 123 may cover the first barrier layer 170. The gate structure 131 is not in contact with the second interlayer insulating layer 123 due to the first barrier layer 170.

Next, a contact hole 180a that passes through the first and second interlayer insulating layers 121 and 123 is formed so as to expose a top surface of an elevated first source/drain 160. After forming the contact hole 180a, a first contact 180 is formed in the contact hole 180a. When the first and second interlayer insulating layers 121 and 123 of FIG. 33 are omitted, FIG. 33 may be the same as FIG. 6.

The foregoing is illustrative of the present inventive concept and is not to be construed as limiting thereof. Although a few embodiments of the present inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the appended claims. The present inventive concept is defined by the following claims, with equivalents of the claims to be included therein.

What is claimed is:

1. A semiconductor device, comprising:
a first fin on a substrate and that extends in a first direction;
a first gate insulating layer including a first trench disposed on the first fin and that extends in a second direction that is different from the first direction;
a first work function adjusting layer in the first trench;
a first barrier layer that is configured to cover a top surface of the first work function adjusting layer; and
an interlayer insulating layer on the first barrier layer.

2. The semiconductor device of claim 1, wherein the first work function adjusting layer includes a second trench that is smaller than the first trench, the device further comprising a first gate metal that is configured to fill the second trench.

3. The semiconductor device of claim 2, wherein the first barrier layer and the first gate metal include the same material.

4. The semiconductor device of claim 3, wherein a cross-section formed by the first barrier layer and the first gate metal includes a T shape.

5. The semiconductor device of claim 1, further comprising:
a second work function adjusting layer between the first gate insulating layer and the first work function adjusting layer,
wherein the second work function adjusting layer includes a third trench, and
wherein the first work function adjusting layer is disposed in the third trench.

6. The semiconductor device of claim 1, wherein the first gate insulating layer and the first work function adjusting layer are not in contact with the interlayer insulating layer.

7. The semiconductor device of claim 1, wherein the substrate comprises:
a first region having the first fin that is formed on the top surface thereof; and
a second region,
the device further comprising: a second fin in the second region;
a second gate insulating layer disposed on the second fin and that includes a fourth trench;
a third work function adjusting layer that includes a fifth trench in the fourth trench;
a fourth work function adjusting layer in the fifth trench; and
a second barrier layer covering a top surface of the fourth work function adjusting layer.

8. The semiconductor device of claim 7, wherein the fourth work function adjusting layer includes a sixth trench that is smaller than the fifth trench,
the device further comprising a second gate metal that fills the sixth trench.

9. The semiconductor device of claim 8, wherein the second barrier layer and the second gate metal include the same material.

10. The semiconductor device of claim 1, wherein the interlayer insulating layer includes an oxygen atom and the first work function adjusting layer includes TiN.

11. The semiconductor device of claim 1, wherein a resistivity of the first barrier layer is lower than a resistivity of the first work function adjusting layer and a resistivity of the first gate insulating layer.

12. A semiconductor device, comprising:
a substrate that includes a first region and a second region;
a first fin on the first region and that extends in a first direction;
a second fin on the second region and that extends in the first direction;
a first gate structure that includes a first width and that is disposed on the first fin;
a second gate structure that includes a second width that is different from the first width and that is disposed on the second fin;
a first barrier layer that is configured to cover a top surface of the first gate structure;
a second barrier layer that is configured to cover a top surface of the second gate structure; and
an interlayer insulating layer that is configured to cover the first barrier layer and the second barrier layer.

13. The semiconductor device of claim 12,
wherein the first gate structure comprises:
a first gate insulating layer that includes a first trench that extends in a second direction that is different from the first direction;
a first work function adjusting layer that includes a second trench in the first trench; and
a first gate metal that is configured to fill the second trench, and
wherein the second gate structure comprises:
a second gate insulating layer that includes a third trench; and
a second work function adjusting layer that is configured to fill the third trench.

14. The semiconductor device of claim 13, wherein the first width is larger than the second width.

15. The semiconductor device of claim 13, wherein the first gate metal and the first barrier layer include the same material.

16. A semiconductor device, comprising:
a fin on a substrate and that extends in a first direction;
a source and a drain that are elevated relative to the fin and that are formed spaced apart from one another in the first direction;
a first interlayer insulating layer formed on the substrate and on the source and drain;
a first gate insulating layer formed in the first interlayer insulating layer and including a first trench disposed on the first fin and that extends in a second direction that is different from the first direction;
a first work function adjusting layer in the first trench;
a first barrier layer that is configured to cover a top surface of the first work function adjusting layer; and
a second interlayer insulating layer on the first barrier layer and on the first interlayer insulating layer.

17. The semiconductor device of claim 16,
wherein the first work function adjusting layer includes a second trench that is smaller than the first trench, the device further comprising a first gate metal that is configured to fill the second trench,
wherein the first barrier layer and the first gate metal include the same material.

18. The semiconductor device of claim 16, further comprising:
a second work function adjusting layer between the first gate insulating layer and the first work function adjusting layer,
wherein the second work function adjusting layer includes a third trench, and
wherein the first work function adjusting layer is disposed in the third trench.

19. The semiconductor device according to claim 16, further comprising a contact that passes through the first and second interlayer insulating layers and that contacts the source and drain.

20. The semiconductor device of claim 16, wherein the first gate insulating layer and the first work function adjusting layer are not in contact with the second interlayer insulating layer.
